(19) United States
(12) Patent Application Publication
(10) Pub. No.: US 2008/0179746 A1
(43) Pub. Date: Jul. 31, 2008

(54) WIRING STRUCTURES OF SEMICONDUCTOR DEVICES AND METHODS OF FORMING THE SAME

(75) Inventors: Won-Goo Hur, Inchon (KR); Dong-Kyun Park, Gyeonggi-do (KR); Je-Hyeon Park, Gyeonggi-do (KR); Young-Joo Cho, Gyeonggi-do (KR); Kyu-Tae Na, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/017,538

(22) Filed: Jan. 22, 2008

(30) Foreign Application Priority Data
Jan. 31, 2007 (KR) 2007-9735

(51) Int. Cl. H01L 23/52; H01L 21/4763

(52) U.S. Cl. 257/751; 438/653; 257/E21.495; 257/E23.141

(57) ABSTRACT

A wiring structure of a semiconductor device comprises an insulating interlayer, a plug and a conductive pattern. The insulating interlayer has an opening therethrough on a substrate. The plug includes tungsten and fills up the opening. The plug is formed by a deposition process using a reaction of a source gas. A conductive pattern structure makes contact with the plug and includes a first tungsten layer pattern and a second tungsten layer pattern. The first tungsten layer pattern is formed by the deposition process. The second tungsten layer pattern is formed by a physical vapor deposition (PVD) process.

### CROSS-REFERENCE TO RELATED APPLICATIONS

This application claims priority under 35 U.S.C. §119 to Korean Patent Application No. 2007-9735, filed on Jan. 31, 2007 in the Korean Intellectual Property Office (KIPO), the contents of which are incorporated herein by reference in their entirety.

### FIELD OF THE INVENTION

The present invention relates generally a wiring of semiconductor devices and, more particularly, to semiconductor device manufacturing.

### BACKGROUND

In a semiconductor device, the wiring structure includes a contact plug, conductive line, etc., and is generally formed using a metal having a low resistance such as aluminum, copper, tungsten, etc. As semiconductor devices have obtained higher degrees of integration, tungsten has been more frequently used for the wiring structure among the above metals, since tungsten has step coverage characteristics superior to those of the other metals and may be easily patterned by a dry-etching process. Additionally, tungsten has a high melting point over 3,400° C., and thus tungsten has a good thermal resistance and an open-circuit failure scarcely occurs due to electromigration in a tungsten wiring structure.

Thus, research has been focused on methods of forming a tungsten wiring structure of a semiconductor device that includes a contact plug and a conductive pattern. A chemical vapor deposition (CVD) process, an atomic layer deposition (ALD) process, a physical vapor deposition (PVD) process, etc. are used as methods of forming tungsten wiring structure for semiconductor devices. The CVD process has good gap filling characteristics, and thus the CVD process has recently been used in forming wiring structures for highly integrated semiconductor device.

However, a tungsten layer formed by a CVD process may have a rough surface. When a tungsten layer is formed by the CVD process, a tungsten source gas and a reducing gas are chemically reacted with each other to form a plurality of independent crystal structures, and thus spaces between the crystal structures may be generated at an upper portion of the tungsten layer. When the tungsten layer has a poor surface morphology, a photoresist may not be properly attached onto the tungsten layer and/or a notch may be formed on a sidewall of a photoresist pattern in a succeeding photolithography process, so that a wiring structure that is formed by patterning the tungsten layer using the photoresist pattern as an etching mask may have a poor profile. Additionally, a protrusion at the upper portion of the tungsten layer may not be completely removed in an etching process, so that a bridge between adjacent wiring structures may be generated.

In order to solve the above problems, after a CVD process is performed in which a hole may be well filled with tungsten to form a first tungsten layer in the hole, the first tungsten layer is polished to form a contact plug. After a PVD process is performed to form a second tungsten layer, the second tungsten layer is patterned to form a tungsten layer pattern on the contact plug. This method is disclosed in Korean Laid-Open Patent Publication No. 2005-52630. However, according to the above method, a chemical mechanical polishing (CMP) process is performed on a top surface of a tungsten layer after forming the tungsten layer by a CVD process. Additionally, a cleaning process and other processes for improving surface characteristics of the tungsten layer are performed after the CMP process. As such, the forming of semiconductor device wiring structures is a complex and expensive process.

### SUMMARY

Embodiments of the present invention provide semiconductor device wiring structures that may be formed by a simple process and that has good surface morphology.

Embodiments of the present invention provide methods of forming semiconductor device wiring structures having good surface morphology (i.e., smooth surface).

According to some embodiments of the present invention, the wiring structure of a semiconductor device comprises an insulating interlayer, a plug and a conductive pattern. The insulating interlayer has an opening therethrough on a substrate. The plug, including tungsten, fills up the opening. The plug is formed by a deposition process using a reaction of a source gas. A conductive pattern structure makes contact with the plug and includes a first tungsten layer pattern and a second tungsten layer pattern. The first tungsten layer pattern is formed by the deposition process. The second tungsten layer pattern is formed by a physical vapor deposition (PVD) process.

In some embodiments, the deposition process may comprise a chemical vapor deposition (CVD) process and an atomic layer deposition (ALD) process.

In some embodiments, the first tungsten layer pattern may have a thickness of about 50% to about 100% of a width of the opening.

In some embodiments, the first tungsten layer may have a thickness of about 100 [symbol] to about 500

[symbol]

In some embodiments, a barrier layer pattern may be formed on a bottom and a sidewall of the opening.

According to some embodiments of the present invention, a method of forming semiconductor device wiring structures includes forming an insulating interlayer having an opening therethrough on a substrate. A deposition process using a reaction of a source gas is performed to form a first metal layer filling up the opening and covering the insulating interlayer. A second metal layer is formed on the first metal layer by a PVD process. The first and second metal layers are patterned to form a plug and a conductive pattern structure. The plug fills up the opening. The conductive pattern structure includes a first metal layer pattern and a second metal layer pattern. The first metal layer pattern is configured to be formed on the plug. The second metal layer is configured to be formed on the first metal layer pattern.

In some embodiments, the deposition process may comprise a CVD process and an ALD process.

In some embodiments, the CVD process may comprise providing tungsten hexafluoride gas and hydrogen gas onto the substrate.

In some embodiments, prior to providing tungsten hexafluoride gas and hydrogen gas, the method may further comprise providing any one of the following onto the substrate: silane (SiH₄) gas, disilane (Si₂H₆) gas, tetrafluorosilane (SiF₄) gas, dichlorosilane (SiCl₂H₂) gas and diborane (B₂H₆) gas.

In some embodiments, forming the first metal layer using the ALD process may comprise repeatedly performing steps i) to iv): i) providing a reducing gas into a chamber containing the substrate; ii) purging the chamber by providing a first purge gas into the chamber; iii) providing a tungsten source gas into the chamber; and iv) purging the chamber by providing a second purge gas into the chamber.

In some embodiments, the first metal layer may have a thickness of about 50% to about 100% of a width of the opening.

In some embodiments, the first metal layer may have a thickness of about 100 [symbol] to about 500

[symbol]

In some embodiments, a barrier layer may be further formed on a bottom and a sidewall of the opening.

According to other embodiments of the present invention, a method of forming semiconductor device wiring structure includes forming a first insulating interlayer having a first opening therethrough that exposes impurity regions in a substrate. A plug including polysilicon doped with impurities is formed in the first opening. A second insulating interlayer having a second opening therethrough is formed on the first insulating interlayer. The second opening exposes the first plug. A deposition process using a reaction of a source gas is performed to form a first metal layer filling up the second opening and covering the second insulating interlayer. A second metal layer is formed on the first metal layer by a PVD process. The first and the second metal layers are patterned to form a contact and a conductive pattern structure. The contact fills up the second opening. The conductive pattern structure includes a first metal layer pattern and a second metal layer pattern. The first metal layer pattern is configured to be formed on the contact. The second metal layer is configured to be formed on the first metal layer pattern.

In some embodiments, the deposition process may comprise a CVD process and an ALD process.

In some embodiments, the first metal layer pattern in the conductive pattern may have a thickness of about 50% to about 100% of a width of the second opening.

According to other embodiments of the present invention, a method of forming semiconductor device wiring structure includes forming a cell gate structure, a string selection line (SSL) and a ground selection line (GSL) on a substrate. A first insulating interlayer is formed on the substrate to cover the cell gate structure, the SSL and the GSL. A common source line (CSL) is formed through the first insulating interlayer. The CSL makes contact with a portion of the substrate adjacent to the GSL. A second insulating interlayer is formed on the first insulating interlayer and the CSL. An opening is formed through the first and second insulating interlayers. A deposition process using a reaction of a source gas is performed to form a first metal layer filling up the opening and covering the second insulating interlayer. A second metal layer is formed on the first metal layer by a PVD process. The first and the second metal layers are patterned to form a plug and a conductive pattern structure. The plug fills up the opening. The conductive pattern structure includes a first metal layer pattern and a second metal layer pattern. The first metal layer pattern is configured to be formed on the plug. The second metal layer is configured to be formed on the first metal layer pattern.

In some embodiments, the deposition process may comprise a CVD process and an ALD process.

In some embodiments, the first metal layer in the conductive pattern structure may have a thickness of about 50% to about 100% of a width of the opening.

Embodiments of the present invention are advantageous because a plug and a conductive pattern electrically connected to the plug are formed by simple, low cost processes. Additionally, the conductive pattern can have an enhanced top surface morphology (i.e., a smooth surface). As such, the occurrence of a bridge phenomenon between adjacent conductive patterns and a cutting phenomenon of the conductive pattern can be reduced.

### BRIEF DESCRIPTION OF THE DRAWINGS

The above and other features and advantages of the present invention will become more apparent by describing in detailed example embodiments thereof with reference to the accompanying drawings, in which:

FIG. 1 is a cross-sectional view illustrating a wiring structure of a semiconductor device in accordance with some embodiments of the present invention;

FIGS. 2 to 5 are cross-sectional views illustrating a method of forming the semiconductor device wiring structure of FIG. 1;

FIG. 6 is a perspective view illustrating a bit line structure in a DRAM device in accordance with some embodiments of the present invention;

FIGS. 7 to 11 are cross-sectional views illustrating a method of forming the bit line structure in the DRAM in FIG. 6;

FIG. 12 is a perspective view illustrating a NAND flash memory device in accordance with some embodiments of the present invention;

FIGS. 13 to 16 are cross-sectional views illustrating a method of manufacturing the NAND flash memory device in FIG. 12;

FIG. 17 is an SEM picture of Comparative Example 1;

FIG. 18 is an SEM picture of Example 1; and

FIG. 19 is an SEM picture of Example 2.

### DETAILED DESCRIPTION

The present invention is described more fully hereinafter with reference to the accompanying drawings, in which some embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Some embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. Hereinafter, the present invention will be explained in detail with reference to the accompanying drawings.

FIG. 1 is a cross-sectional view illustrating the wiring structure of a semiconductor device in accordance with some embodiments of the present invention.

Referring to FIG. 1, a substrate 100 is provided. The substrate 100 may include single crystalline silicon. A conductive structure (not shown) may be formed on the substrate 100.

An insulating interlayer 102 having an opening 104 therethrough is formed on the substrate 100. The insulating interlayer 102 may include silicon oxide. A top surface of the substrate 100 may be exposed by the opening 104. When a conductive structure is formed on the substrate 100, the opening 104 may expose the conductive structure.

When the opening 104 has a width of less than about 300 [symbol] (angstroms), a plug 108a formed in the opening 104 may have a small contact area with the substrate 100, so that the plug 108a may have a high contact resistance. When the opening 104 has a width of more than about 1,000 [symbol] an area in which the plug 108a is formed is so large that a semiconductor device including the plug 108a may not be highly integrated. Thus, the opening 104 may have a width of about 300 [symbol] to about 1,000

[symbol]

A barrier layer pattern 106a is formed on a sidewall and a bottom of the opening 104. The barrier layer pattern 106a may include a metal. In some embodiments of the present invention, the barrier layer pattern 106a has a stacked structure in which a titanium layer and a titanium nitride layer are sequentially stacked.

The plug 108a is formed in the opening 104. The plug 108a may include a metal, for example, tungsten, and the plug 108a may be formed by a deposition process using a reaction of a deposition source gas. The deposition process may include a chemical vapor deposition (CVD) process, an atomic layer deposition (ALD) process, etc. A metal layer formed by a CVD process may have a resistance smaller than that of a metal layer formed by an ALD process, and thus the plug 108a is preferably formed by the CVD process.

A conductive pattern structure 116 is formed on the insulating interlayer 102 to make contact with the plug 108a.

The conductive pattern structure 116 has a structure in which a first metal layer pattern 112 and a second metal layer pattern 114 are sequentially stacked. In some embodiments of the present invention, the first and second metal layer patterns 112 and 114 include tungsten. The first metal layer pattern 112 may be formed by patterning a portion of a first metal layer that has been formed by the deposition process by which the plug 108a is formed. Particularly, when the deposition process is performed, the first metal layer is formed on the substrate 100 and the insulating interlayer 102 to fill up the opening 104. A portion of the first metal layer filling up the opening 102 may be referred to as the plug 108a, and another portion of the first metal layer on the plug 108a and the insulating interlayer 102 may be referred to as the first metal layer pattern 112 after being patterned. The second metal layer pattern 114 may be formed on the first metal layer pattern 112 by a physical vapor deposition (PVD) process.

When the first metal layer pattern 112 in the conductive pattern structure 116 has a thickness smaller than about 50% of a width of the opening 104, the plug 108a may not sufficiently fill up the opening 104. When the first metal layer pattern 112 has a thickness greater than the width of the opening 104, the first metal layer pattern 112 may have a poor surface roughness due to the large thickness thereof. Thus, the first metal layer pattern 112 in the conductive pattern structure 116 may have a thickness of about 50% to about 100% of the width of the opening 104.

The first metal layer pattern 112 is formed by the deposition process using the reaction of the deposition source gas, and thus the first metal layer pattern 112 may have a poor surface morphology when the first metal layer pattern 112 has a thickness of greater than about 500 [symbol] Accordingly, the first metal layer pattern 112 in the conductive pattern structure 116 may have a thickness of smaller than about 500 [symbol] In some embodiments of the present invention, the first metal layer pattern 112 may have a thickness of smaller than about 300 [symbol] in order to obtain a good surface morphology thereof.

When the opening 104 has a width of about 300 [symbol] to about 1,000 [symbol] the first metal layer pattern 112 in the conductive pattern structure 116 may have a thickness of about 150 [symbol] to about 500

[symbol]

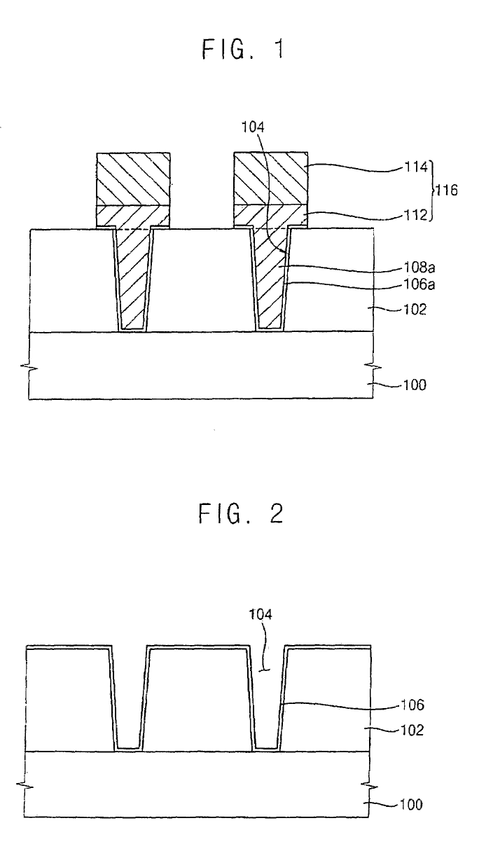

FIGS. 2 to 5 are cross-sectional views illustrating a method of forming the wiring structure of the semiconductor device in FIG. 1.

Referring to FIG. 2, silicon oxide is deposited on the substrate 100 to form an insulating interlayer 102. The substrate 100 may include single crystalline silicon. The insulating interlayer 102 is partially etched by a photolithography process to form an opening 104 exposing a top surface of the substrate 100.

A barrier layer 106 is formed on a sidewall and a bottom of the opening 104 and on the insulating interlayer 102. The barrier layer 106 may be formed using a metal. In some embodiments of the present invention, the barrier layer 106 is formed by sequentially forming a titanium layer and a titanium nitride layer. Particularly, after a titanium layer is formed on the sidewall and the bottom of the opening 104 and on the insulating interlayer 102 by a CVD process using titanium tetrachloride (TiCl₄) gas, a titanium nitride layer is formed on the titanium layer by the CVD process using titanium tetrachloride (TiCl₄) gas and ammonia (NH₃) gas.

When a metal layer is formed by the CVD process using a tungsten source gas such as tungsten hexafluoride (WF₆) gas, the barrier layer 106 may prevent fluoride (F) included in tungsten hexafluoride (WF₆) gas from damaging the insulating interlayer 102 and the substrate 100 as well as serve as an adhesion layer between the insulating interlayer 102 and the metal layer.

When the barrier layer 106 is formed to have only a single titanium layer without a titanium nitride layer, titanium included in the barrier layer 106 and the tungsten source gas used for forming the metal layer may be reacted with each other, so that undesirable by-products such as titanium tetrafluoride (TiF₄) may be generated. Therefore, the barrier layer 106 may be formed to have a stacked structure in which a titanium layer and a titanium nitride layer are sequentially stacked.

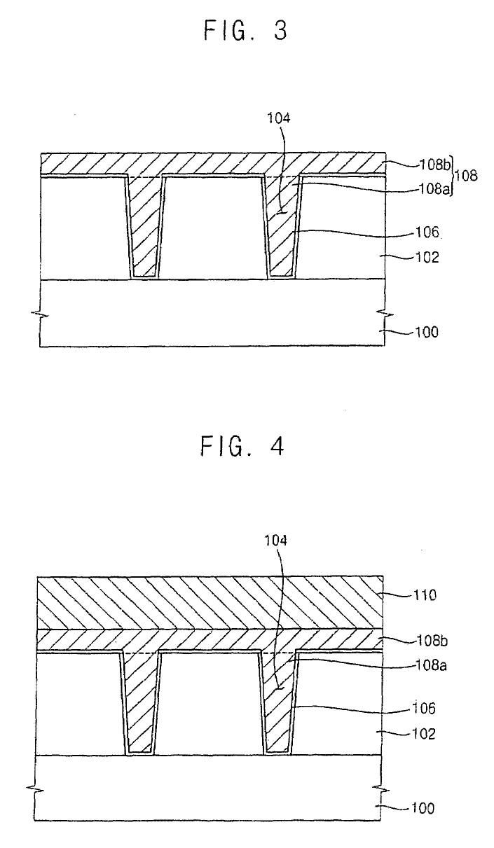

Referring to FIG. 3, a first deposition process using a reaction of a source gas is performed to deposit a metal, for example, tungsten in the opening 104 and on the insulating interlayer 102, thereby forming a first metal layer 108 that fills up the opening 104 and covers the insulating interlayer 102.

The first deposition process may include a CVD process and/or an ALD process. That is, the first metal layer 108 may be formed by the CVD process and/or an ALD process. The first metal layer 108 may be formed by the CVD process because a metal layer formed by the CVD process has a resistance smaller than that of a metal layer formed by the ALD process.

A method of forming the first metal layer 108, for example, a tungsten layer by the CVD process may be described as follows.

A reducing gas and a tungsten source gas are provided into a chamber containing the substrate 100 to form a tungsten seed layer on the barrier layer 106. The reducing gas may include, for example, silane (SiH₄) gas, disilane (Si₂H₆) gas, dichlorosilane (SiCl₂H₂) gas, diborane (B₂H₆) gas, etc. These may be used alone or in a mixture thereof. The tungsten source gas may include, for example, tungsten hexafluoride (WF₆) gas, tungsten hexachloride (WCl₆) gas, tungsten hexacarbonyl (W(CO)₆) gas, etc. These may be used alone or in a mixture thereof.

A hydrogen gas and a tungsten source gas are provided into the chamber to be reacted with a top surface of the tungsten seed layer, thereby forming a tungsten layer serving as the first metal layer 108.

The CVD process may be performed at a temperature of about 360° C. to about 440° C.

When the tungsten layer is formed by the reaction between the hydrogen gas, the tungsten source gas and the tungsten seed layer, the opening 104 may be easily filled up with the tungsten layer. However, alternatively, the tungsten layer may be formed using hydrogen gas and the tungsten source gas without forming the tungsten seed layer.

A method of forming the first metal layer 108, for example, a tungsten layer by the ALD process may be described as follows.

A reducing gas is provided into a chamber containing the substrate 100. The reducing gas may include, for example, silane (SiH₄) gas, disilane (Si₂H₆) gas, dichlorosilane (SiCl₂H₂) gas, diborane (B₂H₆) gas, etc. These may be used alone or in a mixture thereof. When the reducing gas is provided onto the substrate 100, a first portion of the reducing gas is reacted with a top surface of the substrate 100, so that silicon serving as a crystal growth site of tungsten adheres to the top surface of the substrate 100.

A purge gas is provided into the chamber containing the substrate 100. The purge gas may include, for example, nitrogen gas, argon gas, helium gas, etc. These may be used alone or in a mixture thereof. A second portion of the reducing gas, which has not been reacted with the top surface of the substrate 100, may be removed by providing the purge gas onto the substrate 100.

A tungsten source gas is provided onto the substrate 100. The tungsten source gas may include, for example, tungsten hexafluoride (WF₆) gas, tungsten hexachloride (WCl₆) gas, tungsten hexacarbonyl (W(CO)₆) gas, etc. These may be used alone or in a mixture thereof. When the tungsten source gas is provided, tungsten in a first portion of the tungsten source gas is substituted for the silicon adhering to the top surface of the substrate 100, and a second portion of the tungsten source gas, which has not been substituted for the silicon, may be combined with the silicon to be in a gaseous state.

A purge gas is provided onto the substrate 100, and thus the gas including the silicon and an unreacted tungsten source gas may be removed.

As described above, providing the reducing gas, providing the purge gas, providing the tungsten source gas and providing the purge gas may be referred to as a process cycle, and the first metal layer 108 having a desirable thickness may be formed by repeating the process cycle.

In some embodiments, the ALD process may be performed at a temperature of about 300° C. to about 350° C.

Hereinafter, an embodiment in which the first metal layer 108 is formed by the CVD process is illustrated. When a conductive layer is formed by the CVD process, the conductive layer may have a step coverage superior than that formed by a PVD process. Thus, an opening having a high aspect ratio may be filled up with the conductive layer well without voids therein by the CVD process.

The first metal layer 108 is formed to fill up the opening 104. The larger thickness the first metal layer 108 has, the deeper and more spaces are generated between tungsten crystals in the first metal layer 108, each of which grows independently, so that the first metal layer 108 may have a poor surface roughness. Thus, the first metal layer 108 is preferably formed to have a least thickness capable of filling up the opening 104.

Particularly, the first metal layer 108 may have a thickness of about 50% to about 100% of a width of the opening 104. When the first metal layer 108 has a thickness of smaller than about 50% of the width of the opening 104, the opening 104 may not be sufficiently filled up with the first metal layer 108. When the first metal layer 108 has a thickness of greater than the width of the opening 104, the first metal layer 108 may have a poor surface roughness.

Additionally, the first metal layer 108 may have a thickness of smaller than about 500 [symbol] since the first metal layer 108 may have a poor surface morphology (i.e., a rough surface) when the first metal layer 108 has a thickness of greater than about 500 [symbol] The first metal layer 108 preferably has a thickness of less than about 300 [symbol] in order to have a better surface morphology. When the opening 104 has a width of about 300 [symbol] to about 1,000 [symbol] the first metal layer 108 may have a thickness of about 150 [symbol] to about 500

[symbol]

As described above, a plug 108a including tungsten may be formed in the opening 104 by forming the first metal layer 108. That is, a portion of the first metal layer 108 filling up the opening 104 may be referred to as the plug 108a. Additionally, another portion 108b of the first metal layer 108 may be referred to as a first metal layer pattern 112 after being patterned.

Referring to FIG. 4, tungsten is deposited on the first metal layer 108 by a PVD process, so that a second metal layer 110 may be formed on the first metal layer 108. Particularly, the PVD process may be performed at a temperature of about 200° C. and about 400° C. under a chamber pressure of about 10 ntorr and about 100 nTorr with a direct current (DC) power of about 2 kW and about 10 kW. The chamber pressure may be controlled by using an inactive gas provided thereinto.

The second metal layer 110, that is formed by the PVD process may have a resistance lower than that of the first metal layer 108 that is formed by the CVD process. Additionally, the second metal layer 110 may have a surface roughness superior to that of the first metal layer 108.

Thus, in some embodiments of the present invention, a final metal layer structure including the first and second metal layers 108 and 110 may have a smooth surface by forming the first metal layer 108 to have a least thickness capable of filling up the opening 104 and forming the second metal layer 110 having a smooth surface on the first metal layer 108.

However, when the first metal layer 108 has a thickness of greater than about 500 [symbol] the second metal layer 110 formed on the first metal layer 108 may have a poor surface roughness (i.e., a rough surface) due to a poor surface roughness of the first metal layer 108 beneath the second metal layer 110.

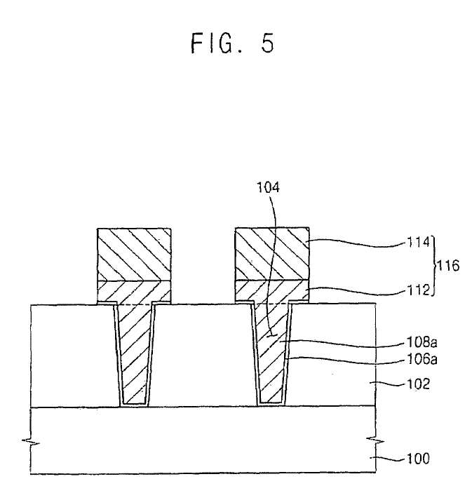

Referring to FIG. 5, a hard mask (not shown) may be formed on the second metal layer 110. For example, the hard mask may be formed by forming a silicon nitride layer on the second metal layer 110, and patterning the silicon nitride layer. The silicon nitride layer may be patterned by a photolithography process.

The second metal layer 110, the first metal layer 108 and the barrier layer 106 are partially etched using the hard mask as an etching mask, so that a conductive pattern structure 116 that includes a first metal layer pattern 112 and a second metal layer pattern 114 and is connected to the plug 108a may be formed. The conductive pattern structure 116 making contact with the plug 108a may have a linear shape extending along a predetermined direction, or an isolated island shape.

The second metal layer 110 has a smooth surface. Thus, in the conductive pattern structure 116 formed by patterning the second metal layer 110, the first metal layer 108 and the barrier layer 106, bridges due to an insufficient etching of protrusions of the conductive pattern structure 116, damages to underlying layers due to an over-etching of recesses of the conductive pattern structure 116, and irregular pattern widths in a photolithography process due to notches of the conductive pattern structure 116 may be decreased.

Accordingly, an additional polishing process may not be required after forming the first metal layer 108. Furthermore, a cleaning process, a surface treatment process, etc. accompanying the polishing process may not be required.

Accordingly, forming a wiring may be simplified, so that the cost for forming the wiring may be reduced.

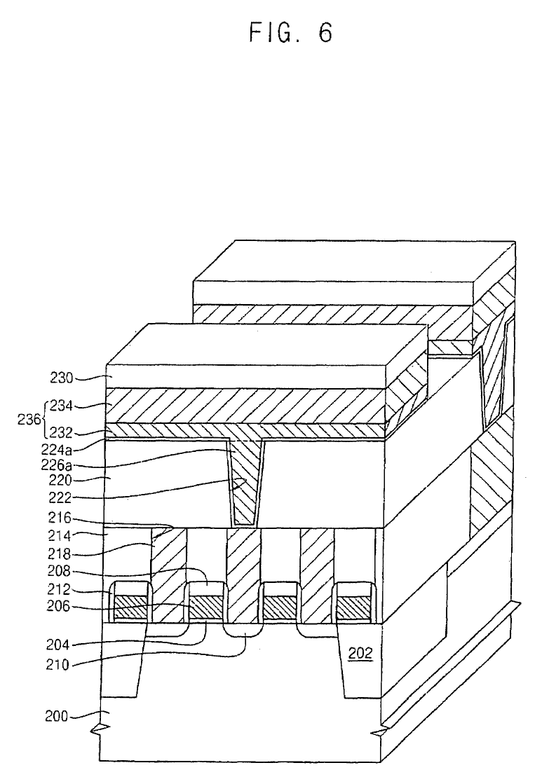

FIG. 6 is a perspective view illustrating a bit line structure in a DRAM device in accordance with some embodiments of the present invention.

A substrate 200 including an active region and an isolation region, which are defined by an isolation layer 202, is provided. A plurality of metal-oxide-semiconductor (MOS) transistors each of which includes a gate insulation layer pattern 204, a gate electrode 206 serving as a word line, and an impurity region 210 is formed on the substrate 200. A first mask 208 including silicon nitride is formed on the gate electrode 206. A spacer 212 is formed on sidewalls of the gate insulation layer pattern 204, the gate electrode 206 and the first hard mask 208.

A first insulating interlayer 214 is formed on the substrate 200 to cover the MOS transistors. The first insulating interlayer 214 may have a flat upper face.

The first insulating interlayer 214 includes a plurality of first openings 216 each of which exposes the impurity region 210. The first openings 216 are self-aligned to a plurality of the spacers 212, respectively. Accordingly, the spacers 212 may be exposed by the first openings 216.

A plurality of plugs 218 are formed in the first openings 216, respectively. The plugs 218 may include polysilicon doped with impurities. Each of the plugs 218 may serve as a landing pad to a bit line contact 226a and be connected to the impurity region 210. When the bit line contact 226a and a storage node contact (not shown) make direct contact with the impurity region 210 of the substrate 200 without the plugs 218, the bit line contact 226a and the storage node contact have heights that are too long. The bit line contact 226a and the storage node contact may have smaller heights by forming the plugs 218 making contact with the bit line contact 226a and the storage node contact in the first openings 216, respectively.

A second insulating interlayer 220 is formed on the plugs 218 and the first insulating interlayer 214. The second insulating interlayer 220 includes a plurality of second openings 222 therethrough and exposes some of the plugs 218. In an embodiment of the present invention, some parts of the plugs 218 making contact with source regions among a plurality of the impurity regions 210 are exposed by the second openings 222, respectively.

A barrier layer pattern 224a is formed on a sidewall and a bottom of each of the second openings 222. The barrier layer 224a may have a structure in which a titanium layer and a titanium nitride layer are sequentially stacked.

A bit line contact 226a including a metal such as tungsten is formed in the second opening 222. The bit line contact 226a may be formed by a deposition process using a reaction of a deposition source gas. The deposition process may include a CVD process and an ALD process. The bit line contact 226a may be formed by a CVD process because a metal layer formed by a CVD process has a resistance smaller than that of a metal layer formed by an ALD process

A bit line 236 is formed on the second insulating interlayer 220 to make contact with the bit line contact 226a. The bit line 236 has a stacked structure in which a first metal layer pattern 232 and a second metal layer pattern 234 are sequentially stacked. In some embodiments of the present invention, the first and second metal layer patterns 232 and 234 include tungsten. The first metal layer pattern 232 may be formed by patterning a portion of a first metal layer that has been formed by the deposition process by which the bit line contact 226a is formed. Particularly, when the deposition process is performed, the first metal layer is formed on the barrier layer pattern 224a to fill up the second opening 222. A portion of the first metal layer filling up the second opening 222 may be referred to as the bit line contact 226a, and another portion of the first metal layer on the bit line contact 226a and the barrier layer pattern 224a may be referred to as the first metal layer pattern 232 after being patterned. The second metal layer pattern 234 may be formed on the first metal layer pattern 232 by a PVD process.

The first metal layer pattern 232 in the bit line 236 may have a thickness of about 50% to about 100% of a width of the second opening 222. In some embodiments of the present invention, the first metal layer 232 in the bit line 236 has a thickness less than about 500

[symbol]

A third insulating interlayer (not shown) covering the bit line 232, a storage node contact (not shown) connected to a drain region among the impurity regions 210 through the second insulating interlayer 220 and the third insulating interlayer, and a capacitor connected to the storage node contact may be further formed so that a DRAM device is constructed.

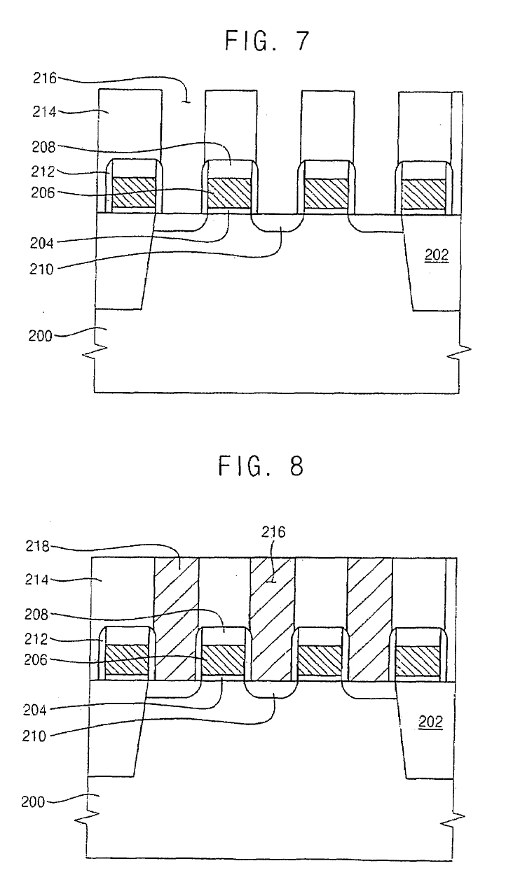

FIGS. 7 to 11 are cross-sectional views illustrating a method of forming the bit line structure in the DRAM in FIG. 6.

Referring to FIG. 7, an isolation process such as a shallow trench isolation (STI) process is performed on a substrate 200 to form an isolation layer 202 at an upper portion of the substrate 200. An active region and a field region may be defined by the isolation layer 202.

A gate insulation layer, a conductive layer and a first hard mask 208 are formed on the substrate 200. The conductive layer and the gate insulation layer are partially removed by an etching process using the first hard mask 208 as an etching mask to form a gate insulation layer pattern 204 and a gate electrode 206 on the substrate 200. Impurities are implanted onto upper portions of the substrate 200 adjacent to the gate electrode 206, thereby forming a plurality of impurity regions 210. A MOS transistor including the gate insulation layer pattern 204, the gate electrode 206 and the impurity region 210 is formed by the above processes.

A gate spacer 212 including silicon nitride is formed on sidewalls of the first hard mask 208, the gate electrode 206 and the gate insulation layer pattern 204.

An insulating layer is formed on the substrate 200 to cover the MOS transistor, and a top surface of the insulating layer is polished by a chemical mechanical polishing (CMP) process and/or an etch-back process to form a first insulating interlayer 214.

The first insulating interlayer 214 is partially removed by a photolithography process so that a plurality of first openings 216 exposing the impurity regions 210, respectively, are formed through the first insulating interlayer 214. The openings 216 are self-aligned to a plurality of the gate spacers 212. Accordingly, the gate spacers 212 may be exposed by the first openings 216, respectively.

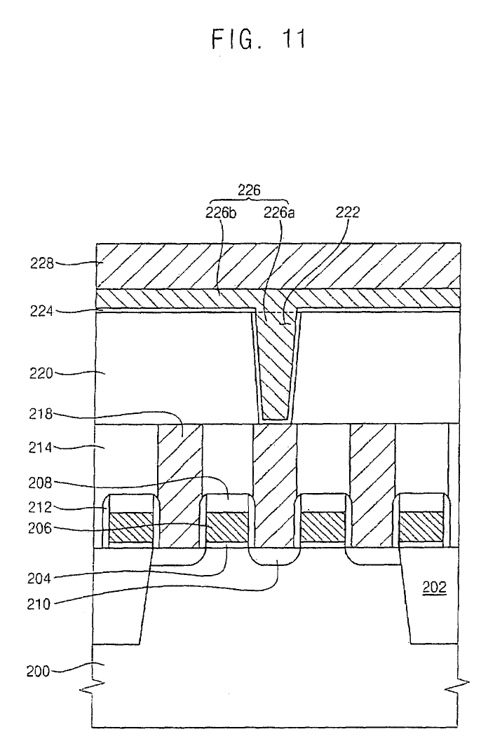

Referring to FIG. 8, a polysilicon layer doped with impurities is formed on the substrate 200 and the first insulating interlayer 214 to fill up the openings 216. A top surface of the polysilicon layer may be planarized until the first insulating interlayer 214 is exposed by a CMP process and/or an etch-back process, so that a plurality of plugs 218 making contact with the impurity regions 210, respectively, is formed in the opening 216. In the present embodiment, some parts of the plugs 218 making contact with a source region among the impurity regions 210 are electrically connected to a bit line contact 226a (see FIG. 10), and other parts of the plugs 218 making contact with a drain region among the impurity regions 210 are electrically connected to a capacitor (not shown).

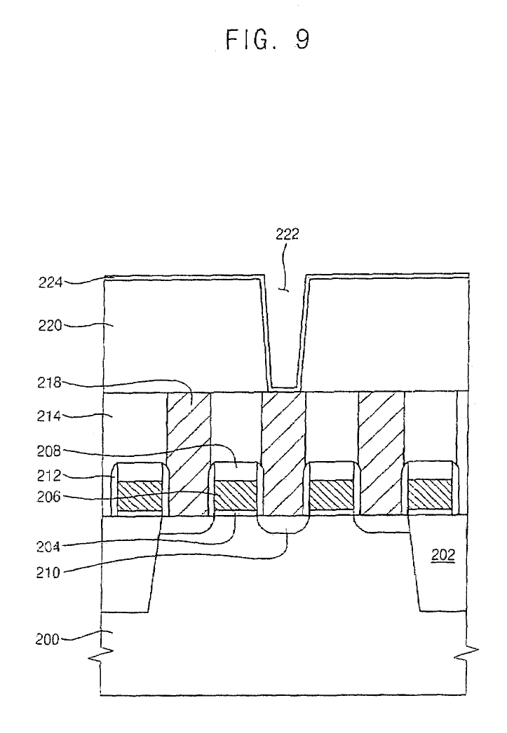

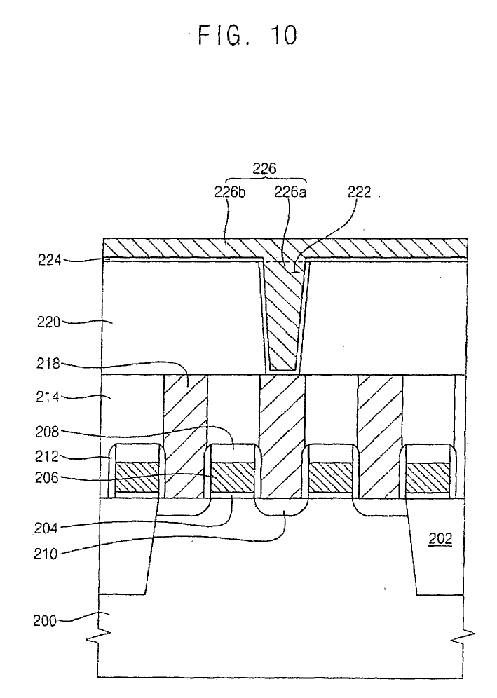

Referring to FIG. 9, a second insulating interlayer 220 is formed on the first insulating interlayer 214 and the plugs 218. The second insulating interlayer 220 is partially removed by a photolithography process, so that a second opening 222 is formed through the second insulating interlayer 220 to expose a top surface of the plug 218.

A barrier layer 224 is formed on a sidewall and a bottom of the second opening 222 and on the second insulating interlayer 220. The barrier layer 224 may be formed by sequentially forming a titanium layer and a titanium nitride layer. Particularly, after a titanium layer is formed on the sidewall and the bottom of the second opening 222 and on the second insulating interlayer 220 by a CVD process using titanium tetrachloride (TiCl₄) gas, a titanium nitride layer is formed on the titanium layer by the CVD process using titanium tetrachloride (TiCl₄) gas and ammonia (NH₃) gas.

Referring to FIG. 10, a deposition process using a reaction of a source gas is performed, so that a first metal layer 226, for example, a tungsten layer, which fills up the second opening 222 and covers the barrier layer 224, is formed. The deposition process may include a CVD process and/or an ALD process. That is, the first metal layer 226 may be formed by a CVD process and/or an ALD process. The first metal layer 226 may be formed by a CVD process because a metal layer formed by a CVD process has a resistance smaller than that of a metal layer formed by an ALD process.

The first metal layer 226 has a thickness of about 50% to about 100% of a width of the second opening 222. The first metal layer 226 may have a thickness of about 150 [symbol] to about 500 [symbol] The first metal layer 226 may have a thickness of smaller than about 300

[symbol]

A bit line contact 226a including a metal such as tungsten may be formed in the second opening 222 by forming the first metal layer 226. Particularly, when the deposition process is performed, the first metal layer 226 is formed on the barrier layer 224 to fill up the second opening 222. A portion 226a of the first metal layer 226 filling up the second opening 222 may be referred to as the bit line contact 226a, and another portion 226b of the first metal layer 226 on the bit line contact 226a and the barrier layer pattern 224a may be referred to as a first metal layer pattern 232 (see FIG. 6) after being patterned.

Referring to FIG. 11, a second metal layer 228, for example, a tungsten layer is formed on the first metal layer 226 by a PVD process. The second metal layer 228 may have a resistance lower than that of the first metal layer 226. The second metal layer 228 formed by the PVD process has a surface that is generally smoother than that of the first metal layer 226.

Referring to FIG. 6 again, a second hard mask 230 is formed on the second metal layer 228. The second hard mask 230 may be formed using silicon nitride. The second metal layer 228, the first metal layer 226 and the barrier layer 224 are partially etched using the second hard mask 230 as an etching mask, so the a bit line 236 making contact with the bit line contact 226a may be formed. The bit line 236 extends in a direction substantially perpendicular to that in which the gate electrode 206 serving as a word line extends. The bit line 236 has a structure in which the first metal layer pattern 232 and the second metal layer pattern 234 are sequentially stacked.

A spacer (not shown) may be formed on sidewalls of the bit line 236 and the second hard mask 230.

A third insulating interlayer (not shown) may be formed on the second insulating interlayer 220 to cover the bit line 234. A storage node contact (not shown) may be formed through the third insulating interlayer and the second insulating interlayer 220 to make contact with some of the plugs 218 connected to the drain region. A capacitor may be formed to be electrically connected to the storage node contact. As a result, the DRAM device may be formed by the above method.

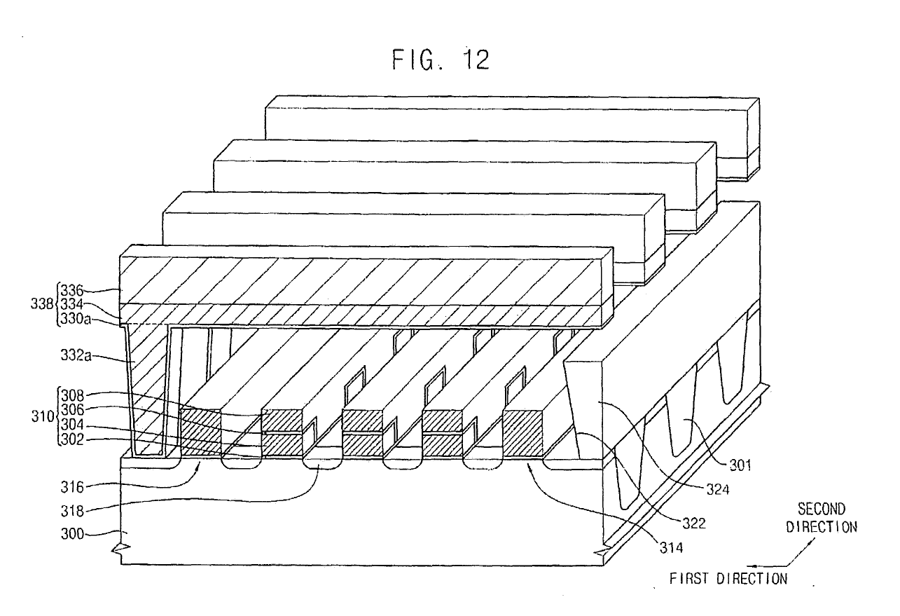

FIG. 12 is a perspective view illustrating a NAND flash memory device in accordance with some embodiments of the present invention.

A substrate 300 including an active region and a field region is provided. The active region and the field region are defined by an isolation layer 301. The isolation layer 301 has a linear shape extending in a first direction, so that the active region and the field region may be alternately formed in a second direction perpendicular to the first direction in the substrate 300.

A tunnel insulation layer 302 is formed on the substrate 300. A plurality of floating gate electrodes 304 are formed on the tunnel insulation layer 302. Each of the floating gate electrodes 304 may have an island shape, and the floating gate electrodes 304 may be regularly formed at a predetermined distance from each other.

A dielectric layer 306 is formed on the floating gate electrodes 304 and the tunnel insulation layer 302. The dielectric layer 306 may have a stacked structure in which a silicon oxide layer, a nitride oxide layer and a silicon oxide layer are sequentially stacked. The dielectric layer 306 may include a metal oxide having a dielectric constant higher than that of silicon oxide.

A plurality of control gates 308 are formed on the dielectric layer 306 to have a linear shape extending in a second direction substantially perpendicular to the first direction. The control gates 308 control the floating gate electrodes 304 that are repeatedly disposed in the second direction.

Hereinafter, a structure in which the tunnel insulation layer 302, the floating gate electrode 304, the dielectric layer 306 and the control gate electrode 308 are sequentially stacked may be referred to as a cell gate structure 310. A plurality of impurity regions 318 are formed at upper portions of the substrate 300 adjacent to a plurality of the cell gate structures 310.

In a NAND flash memory device, for example, 32 control gate electrodes disposed in the first direction may compose a unit, and reading and writing operations may be performed by the unit. A ground selection line (GSL) 314 and a string selection line (SSL) 316 are formed at both ends of the unit, respectively. Each of the GSL 314 and the SSL 316 may have substantially the same structure as that of a common MOS transistor. That is, the GSL 314 and the SSL 316 may have a structure in which a gate insulation layer pattern and a gate electrode are sequentially stacked. The impurity regions 318 may be also formed at upper portions of the substrate 300 adjacent to the GSL 314 and the SSL 316.

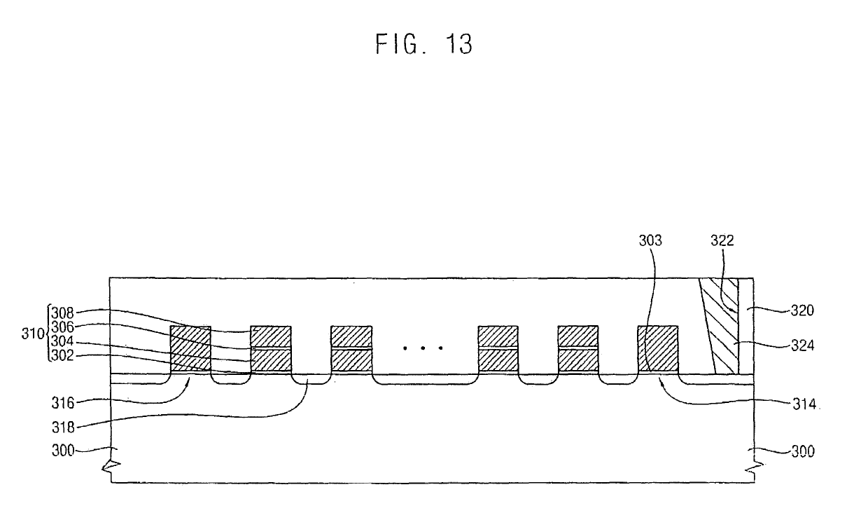

A first insulating interlayer 320 (see FIG. 13) is formed on the substrate 300 to cover the cell gate structures 310, the GSL 314 and the SSL 316.

A trench 322 is formed through the first insulating interlayer 320 to expose a first upper portion of the substrate 300 adjacent to the GSL 314. The trench 322 may have a linear shape extending in the second direction. A common source line (CSL) 324 filled with a conductive material is formed in the trench 322. The CSL 324 may a linear shape extending in the second direction.

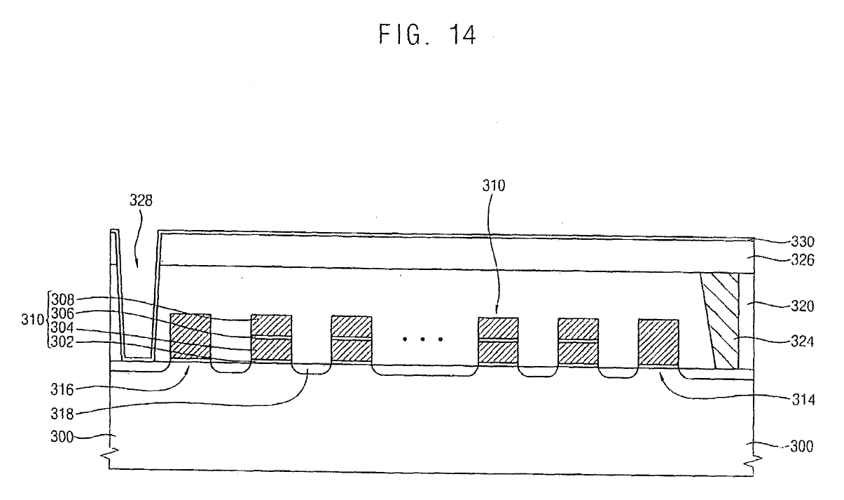

A second insulating interlayer 326 (see FIG. 14) is formed on the first insulating interlayer 320.

An opening 328 (see FIG. 14) is formed through the first and second insulating interlayers 320 and 326 to expose a second upper portion of the substrate 300 adjacent to the SSL 316 at which the impurity region 318 is formed.

A barrier layer pattern 330a is formed on a sidewall and a bottom of the opening 328. The barrier layer pattern 330a may have a structure in which a titanium layer and a titanium nitride layer are sequentially stacked.

A plug 332a including a metal such as tungsten is formed in the opening 328. The plug 332a may be formed by a deposition process using a reaction of a deposition source gas. The deposition process using the reaction of the deposition source gas may include a CVD process and/or an ALD process.

A bit line 338 is formed on the second insulating interlayer 326 to make contact with the plug 332a. The bit line 338 has a structure in which a first metal layer pattern 334 and a second metal layer pattern 336 are sequentially stacked. In an example embodiment of the present invention, the first and second metal layer patterns 334 and 336 include tungsten. The first metal layer pattern 334 may be formed by patterning a portion of a first metal layer that has been formed by the deposition process by which the plug 332a is formed. Particularly, when the deposition process is performed, the first metal layer is formed on the barrier layer pattern 330a to fill up the opening 328. A portion of the first metal layer filling up the opening 328 may be referred to as the plug 332a, and another portion of the first metal layer on the plug 332a and the barrier layer pattern 330a may be referred to as the first metal layer pattern 334 after being patterned. The second metal layer pattern 336 may be formed on the first metal layer pattern 334 by a PVD process.

The first metal layer pattern 334 in the bit line 338 may have a thickness of about 50% to about 100% of a width of the second opening 328. In an example embodiment of the present invention, the first metal layer pattern 334 in the bit line 338 has a thickness less than about 500

[symbol]

FIGS. 13 to 16 are cross-sectional views illustrating a method of manufacturing the NAND flash memory device in FIG. 12.

Referring to FIG. 13, an isolation process such as a STI process is performed on a substrate 300 to form an isolation layer (not shown) at an upper portion of the substrate 300. The substrate 300 may include single crystalline silicon. An active region and a field region may be defined by the isolation layer.

Particularly, the substrate 300 is partially etched to form a trench (not shown) extending in a first direction. The trench is filled with an insulating material to form the isolation layer. The isolation layer may have a linear shape extending in the first direction, so that the active region and the field region may be alternately defined in a second direction perpendicular to the first direction in the substrate 300.

A plurality of cell gate structures 310, a SSL 316 and a GSL 314 are formed on the substrate 300.

Particularly, an oxide layer is formed on the substrate 300. The oxide layer may be formed only on the active region of the substrate 300. The oxide layer may serve as a tunnel insulation layer pattern 302 and a gate insulation layer pattern 303. A first conductive layer is formed on the oxide layer. The first conductive layer and the oxide layer are partially etched by a photolithography process, so that a floating gate electrode 304, the tunnel insulation layer pattern 302 and the gate insulation layer pattern 303 each of which has a linear shape extending in a second direction perpendicular to the first direction may be formed on the substrate 300. Additionally, the floating gate electrode 304 may be partially etched to have an island shape. A dielectric layer is formed on the floating gate electrode 304, the tunnel insulation layer pattern 302 and the substrate 300. The dielectric layer may have a stacked structure in which a silicon oxide layer, a nitride oxide layer and a silicon oxide layer are sequentially stacked. The dielectric layer 306 may include a metal oxide having a dielectric constant higher than that of silicon oxide.

A second conductive layer is formed on the dielectric layer.

The second conductive layer and the dielectric layer may be partially removed by an etching process using a photoresist pattern (not shown) to form a control gate electrode 308 and a dielectric layer pattern 306, respectively. Each of the control gate electrode 308 and the dielectric layer pattern 306 may have a linear shape extending in the second direction. Thus, the cell gate structures 310 each of which includes the tunnel insulation layer pattern 302, the floating gate electrode 304, the dielectric layer pattern 306 and the control gate electrode 308 may be formed. Each of the cell gate structure 310 may have a linear shape extending in the second direction. When the cell gate structures 310 are formed by the above process, the SSL 316 and the GSL 314 may be also formed on the substrate 300.

Impurity regions 318 are formed at upper portions of the substrate 300 adjacent to the cell gate structures 310, the SSL 316 and the GSL 314.

A first insulating interlayer 320 is formed on the substrate 300 to cover the cell gate structures 310, the SSL 316 and the GSL 314.

The first insulating interlayer 320 is partially removed by an etching process to form a trench 322 exposing a top surface of the substrate 300 adjacent to the GSL 314. The trench 322 may have a linear shape extending in the second direction. A conductive layer is formed to fill up the trench 322, and a top surface of the conductive layer is polished by a CMP process and/or an etch-back process until the first insulating interlayer 320 is exposed, so that a CSL 324 may be formed.

Referring to FIG. 14, a second insulating interlayer 326 is formed on the first insulating interlayer 320 and the CSL 324. The first and second insulating interlayers 320 and 324 are partially removed by an etching process to form an opening 328 exposing a portion of the impurity regions 318 adjacent to the SSL 316. A plurality of the openings 328 may be formed to expose a plurality of the portions of the impurity regions 318 adjacent to a plurality of the SSL 316, respectively.

A barrier layer 330 is formed on a bottom and a sidewall of the opening 328 and the second insulating interlayer 326. The process for forming the barrier layer 330 is substantially the same as that illustrated with reference to FIG. 9. Thus, repetitive explanation on the process forming the barrier layer 330 is omitted.

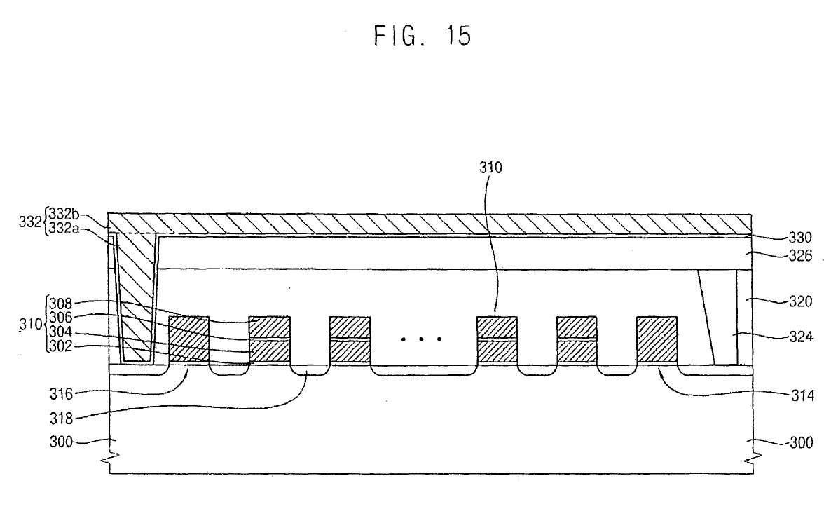

Referring to FIG. 15, a deposition process using a reaction of a source gas is performed, so that a first metal layer 332, for example, a tungsten layer, which fills up the opening 328 and covers the barrier layer 330, is formed. The deposition process may include a CVD process and/or an ALD process. That is, the first metal layer 332 may be formed by a CVD process and/or an ALD process. The first metal layer 332 may be formed by a CVD process because a metal layer formed by a CVD process has a resistance smaller than that of a metal layer formed by an ALD process.

The first metal layer 332 has a thickness of about 50% and about 100% of a width of the opening 328. The first metal layer 332 may have a thickness of about 150 [symbol] and about 500 [symbol] The first metal layer 332 may have a thickness less than about 300

[symbol]

A plug 332a including a metal such as tungsten may be formed in the opening 328 by forming the first metal layer 332. Particularly, when the deposition process is performed, the first metal layer 332 is formed on the barrier layer 330 to fill up the opening 328. A portion 332a of the first metal layer 332 filling up the opening 328 may be referred to as the plug 332a, and another portion 332b of the first metal layer 332 on the plug 332a and the barrier layer 330 may be referred to as a first metal layer pattern 334 (see FIG. 16) after being patterned.

Referring to FIG. 16, a second metal layer, for example, a tungsten layer is formed on the first metal layer 332 by a PVD process. The second metal layer may have a resistance lower than that of the first metal layer 332. The second metal layer formed by the PVD process has a surface that is smaller than that of the first metal layer 332.

A second hard mask (not shown) is formed on the second metal layer. The second metal layer, the first metal layer 332 and the barrier layer 330 are sequentially etched using the second hard mask to form a bit line 338 that includes the first metal layer pattern 334 and a second metal layer pattern 336, and makes contact with the plug 332a. The bit line 338 may extend in the first direction.

### COMPARATIVE EXAMPLE

A tungsten layer having a thickness of about 1,000 [symbol] was formed on a single crystalline silicon substrate by a CVD process. Then, a cross-section of the tungsten layer was observed by a scanning electron microscope (SEM).

### EXAMPLE 1

After forming a first tungsten layer having a thickness of about 300 [symbol] on a single crystalline silicon substrate by a CVD process, a second tungsten layer having a thickness of about 700 [symbol] was formed on the first tungsten layer by a PVD process. Then, a cross-section of the first and second tungsten layers was observed by an SEM.

### EXAMPLE 2

After forming a first tungsten layer having a thickness of about 300 [symbol] on a single crystalline silicon substrate by an ALD process, a second tungsten layer having a thickness of about 700 [symbol] was formed on the third tungsten layer by a PVD process. Then, a cross-section of the first and second tungsten layers was observed by an SEM.

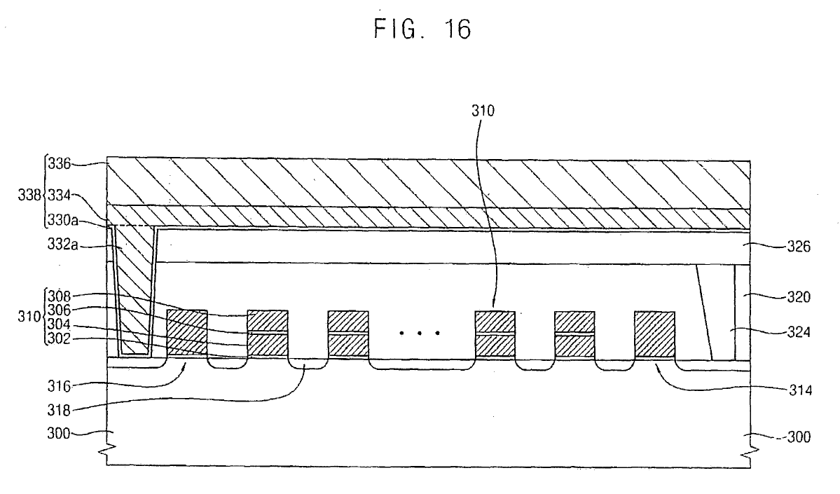

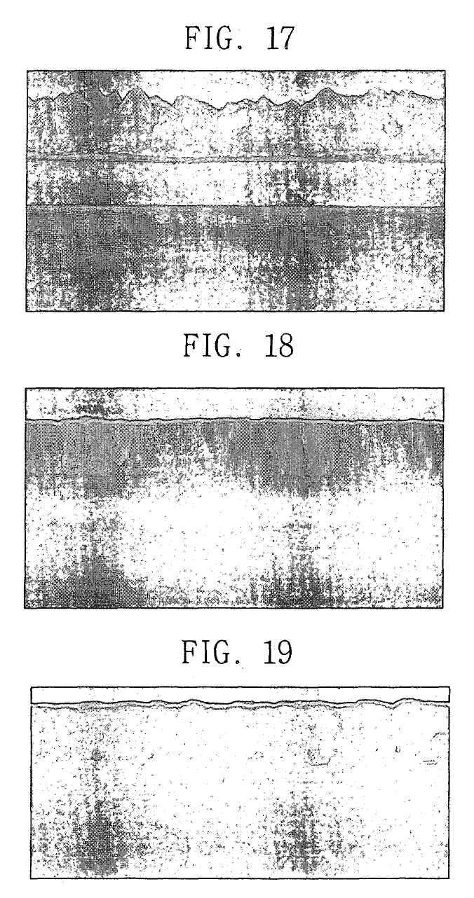

FIG. 17 is an SEM picture of Comparative Example, FIG. 18 is an SEM picture of Example 1, and FIG. 19 is an SEM picture of Example 2.

As shown in FIG. 17, when a tungsten layer having a thickness of about 1,000 [symbol] was formed by a CVD process, the tungsten layer had a poor surface morphology (i.e., the tungsten layer has a rough surface).

Meanwhile, as shown FIG. 18, when a first tungsten layer formed by the CVD process and a second tungsten layer formed by a PVD process are stacked, the second tungsten layer has a surface morphology superior than that of the tungsten layer of Comparative Example (i.e., the second tungsten layer has a smoother surface than the tungsten layer in FIG. 17).

Additionally, as shown FIG. 19, when a first tungsten layer formed by an ALD process and a second tungsten layer formed by the PVD process are stacked, the first tungsten layer has a surface morphology superior than that of the tungsten layer of Comparative Example (i.e., the first tungsten layer has a smoother surface than the tungsten layer in FIG. 17).

According to the results, when a tungsten layer is formed by methods of Example 1 and Example 2, the tungsten layers have a surface morphology superior (i.e., a smoother surface) than that of a tungsten layer formed only by a CVD process.

According to some example embodiments of the present invention, a plug and a conductive pattern electrically connected to the plug may be formed by a simple method. Additionally, the conductive pattern may have a good surface morphology (i.e., smooth surface), and thus bridges between portions of the conductive pattern adjacent to each other and breaking-down of the conductive pattern may be reduced. Accordingly, the wiring structure of a semiconductor device having a high performance may be formed at a low cost.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A wiring structure of a semiconductor device, comprising:
an insulating interlayer which includes an opening therethrough;
a plug comprising tungsten that fills up the opening, the plug being formed by a deposition process using a reaction of a source gas; and
a conductive pattern structure in contact with the plug and including a first tungsten layer pattern and a second tungsten layer pattern, the first tungsten layer pattern being formed by the deposition process, the second tungsten layer pattern being formed by a physical vapor deposition (PVD) process.

2. The wiring structure of claim 1, wherein the deposition process comprises a chemical vapor deposition (CVD) process and an atomic layer deposition (ALD) process.

3. The wiring structure of claim 1, wherein the first tungsten layer pattern has a thickness of about 50% to about 100% of a width of the opening.

4. The wiring structure of claim 1, wherein the first tungsten layer has a thickness of about 100 [symbol] to about 500

[symbol]

5. The wiring structure of claim 1, further comprising a barrier layer pattern on a bottom and a sidewall of the opening.

6. A method of forming a wiring structure of a semiconductor device, the method comprising:
forming an insulating interlayer having an opening therethrough on a substrate;
performing a deposition process using a reaction of a source gas to form a first metal layer that fills up the opening and covers the insulating interlayer;
forming a second metal layer on the first metal layer by a PVD process; and
patterning the first and second metal layers to form a plug and a conductive pattern structure, wherein the plug fills up the opening, wherein the conductive pattern structure includes a first metal layer pattern and a second metal layer pattern, wherein the first metal layer pattern is formed on the plug, and wherein the second metal layer is formed on the first metal layer pattern.

7. The method of claim 6, wherein the deposition process comprises a CVD process and an ALD process.

8. The method of claim 7, wherein the CVD process comprises providing tungsten hexafluoride gas and hydrogen gas onto the substrate.

9. The method of claim 8, further comprising providing any one of the following gases onto the substrate prior to providing tungsten hexafluoride gas and hydrogen gas onto the substrate: silane (SiH₄) gas, disilane (Si₂H₆) gas, tetrafluorosilane (SiF₄) gas, dichlorosilane (SiCl₂H₂) gas and diborane (B₂H₆) gas.

10. The method of claim 7, wherein forming the first metal layer using the ALD process comprises repeatedly performing steps i) to iv):
i) providing a reducing gas into a chamber containing the substrate;
ii) purging the chamber by providing a first purge gas into the chamber;
iii) providing a tungsten source gas into the chamber; and
iv) purging the chamber by providing a second purge gas into the chamber.

11. The method of claim 10, wherein the reducing gas comprises any one selected from the group consisting of silane (SiH₄) gas, disilane (Si₂H₆) gas, tetrafluorosilane (SiF₄) gas, dichlorosilane (SiCl₂H₂) gas and diborane (B₂H₆) gas.

12. The method of claim 6, wherein the first metal layer has a thickness of about 100 [symbol] to about 500

[symbol]

13. The method of claim 6, wherein the first metal layer has a thickness of about 50% to about 100% of a width of the opening.

14. The method of claim 6, further comprising forming a barrier layer on a bottom and a sidewall of the opening.

15. A method of forming a wiring structure of a semiconductor device, the method comprising:
forming a first insulating interlayer on a substrate, wherein the first insulating interlayer has a first opening therethrough that exposes impurity regions in the substrate;
forming a plug including polysilicon doped with impurities in the first opening;
forming a second insulating interlayer on the first insulating interlayer, wherein the second insulating interlayer has a second opening therethrough that exposes the first plug;
performing a deposition process using a reaction of a source gas to form a first metal layer that fills up the second opening and covers the second insulating interlayer;
forming a second metal layer on the first metal layer by a PVD process; and
patterning the first and the second metal layers to form a contact and a conductive pattern structure, wherein the contact fills up the second opening, wherein the conductive pattern structure includes a first metal layer pattern and a second metal layer pattern, wherein the first metal layer pattern is formed on the contact, and wherein the second metal layer is formed on the first metal layer pattern.

16. The method of claim 15, wherein performing the deposition process comprises a CVD process and an ALD process.

17. The method of claim 15, wherein the first metal layer pattern in the conductive pattern has a thickness of about 50% to about 100% of a width of the second opening.

18. A method of forming a wiring structure of a semiconductor device, the method comprising:
forming a cell gate structure, a string selection line (SSL) and a ground selection line (GSL) on a substrate;
forming a first insulating interlayer on the substrate to cover the cell gate structure, the SSL and the GSL;
forming a common source line (CSL) through the first insulating interlayer, the CSL making contact with a portion of the substrate adjacent to the GSL;
forming a second insulating interlayer on the first insulating interlayer and the CSL;
forming an opening through the first and second insulating interlayers;
performing a deposition process using a reaction of a source gas to form a first metal layer that fills up the opening and covers the second insulating interlayer;
forming a second metal layer on the first metal layer by a PVD process; and
patterning the first and the second metal layers to form a plug and a conductive pattern structure, wherein the plug fills up the opening, wherein the conductive pattern structure includes a first metal layer pattern and a second metal layer pattern, wherein the first metal layer pattern is formed on the plug, and wherein the second metal layer is formed on the first metal layer pattern.

19. The method of claim 18, wherein performing the deposition process comprises a CVD process and an ALD process.

20. The method of claim 18, wherein the first metal layer in the conductive pattern structure has a thickness of about 50% to about 100% of a width of the opening.
